(19) United States
(12) Patent Application Publication
(10) Pub. No.: US 2024/0348240 A1
(43) Pub. Date: Oct. 17, 2024

(54) REDUNDANT ACTIVE DISCHARGE CIRCUIT AND CONTROL METHOD, AND INVERTER

(71) Applicant: ZF Friedrichshafen AG, Friedrichshafen (DE)

(72) Inventors: Zhenhua Jing, Shanghai (CN); Dong Li, Shanghai (CN); Zhiwu Hu, Shanghai (CN)

(73) Assignee: ZF Friedrichshafen AG, Friedrichshafen (DE)

(21) Appl. No.: 18/637,784

(22) Filed: Apr. 17, 2024

(30) Foreign Application Priority Data
Apr. 17, 2023 (CN) 202310407202.7

(51) Int. Cl. H03K 17/06; H03K 7/08; H03K 17/567

(52) U.S. Cl. CPC H03K 17/06; H03K 7/08; H03K 17/567

(57) ABSTRACT

A redundancy active discharge circuit includes a power transistor module connected to a discharge element to dissipate energy stored in the discharge element; a PWM wave generation module to generate a PWM wave with a pulse width less than a turn-on process time of a transistor of the power transistor module, the PWM wave providing a drive signal for the transistor; a driving module to receive and amplify the drive signal to drive the transistor; and a switch module to control on-off of the redundancy discharge circuit. A control method includes controlling a redundancy discharge circuit to turn on, controlling a transistor Q1 to turn on, and generating a low duty cycle PWM wave by a PWM wave generation module to control the operation of a transistor Q2.

### CROSS-REFERENCE TO RELATED APPLICATION

This application claims priority to China Application No. 202310407202.7, filed on Apr. 17, 2023, the entirety of which is hereby fully incorporated by reference herein.

### FIELD

The present disclosure mainly relates to the technical field of discharge circuits, and in particular, to a redundancy active discharge circuit and a control method therefor, and an inverter.

### BACKGROUND

In a circuit, discharging the circuit generally refers to discharging electricity in a large capacitor in the circuit. For example, some high-voltage capacitors may have high voltage or electric energy retained after power-off. In order to prevent excessive energy from damaging a device, it is necessary to dissipate or release excess energy from the circuit. Therefore, a corresponding discharge circuit can be designed to achieve the purpose of discharge.

The discharge circuit is generally applied in scenarios where a power supply needs to be switched on and off quickly and repeatedly and there is a large-capacity capacitor in the load circuit. After a power switch is disconnected, if there is a large capacitor in the load circuit, this may cause a voltage in the load circuit to drop slowly. In this case, if the power switch is re-connected, the load circuit is re-powered on without being completely de-energized, which may lead to a failure of the circuit to properly reset for startup, then resulting in an abnormal operation of the circuit, such as the concurrence of a startup crash, or even damage to an electronic device in severe case. In daily life, when an electronic device is restarted by switching a power supply on and off, the power supply is generally switched on after a few seconds upon power-off, such as to restart a router. Some devices, such as televisions, may have their LED indicator lights gone out after a few seconds upon power-off, which is caused by a failure to rapidly discharge residual electricity.

A drive system for an electric vehicle includes a power battery, an inverter, and a traction motor, and the inverter is used for power conversion between the traction battery and the motor. Generally, the drive motor is a three-phase motor, and the inverter includes legs of three phases for converting a direct current supplied by the traction battery into an alternating current for the drive motor. A high side of a leg of each phase of the inverter is connected to a positive electrode of the traction battery, a low side thereof is connected to a negative electrode of the traction battery, and a midpoint thereof is connected to one phase of winding of the drive motor. Generally, the drive system further includes a filter capacitor, which is connected to the positive and negative electrodes of the traction battery and connected in parallel with the legs of the inverter. When redundancy discharge is required in the case of a fault, if high-voltage charges stored in the filter capacitor are not discharged in a timely manner, a safety accident may occur.

Existing discharge circuit designs mainly involve the use of a power resistor for discharging, along with the addition of a microcontroller and some logic circuits on the high-voltage side. The use of the power resistor for discharging means that a discharge resistor is required, which is generally connected in parallel with the capacitor. When the power supply fluctuates, the capacitor may charge and discharge accordingly. If no discharge resistor is connected in parallel with the capacitor, charge and discharge currents may flow out from one end of the capacitor and return to the other end of the capacitor through a working loop, which may seriously interfere with the stable operation of the circuit. When the discharge resistor is connected in parallel with the capacitor, the discharge resistor may absorb discharge energy, i.e., the power absorbed by the discharge resistor may allow a large amount of heat to be generated by the resistor itself, which then converts electric energy into thermal energy. In addition, the microcontroller is a single-chip microcomputer that integrates main parts of a microcomputer on one chip. Therefore, the above discharge circuit has a high cost and requires complicated thermal design, circuit design, and tests. Moreover, as the discharge control is implemented by the microcontroller, corresponding software control programming is required.

### SUMMARY

A technical problem to be solved by the present disclosure is to provide a redundancy active discharge circuit and a control method therefor, and an inverter, which can implement a redundancy active discharge function only through simple logic control, and has the advantages of low cost, easy implementation, no need for software programming, and the like.

In order to solve the above technical problems, according to a first aspect, the present disclosure provides a redundancy active discharge circuit, the circuit including: a power transistor module including a transistor, the power transistor module being connected to a discharge element and configured to dissipate energy stored in the discharge element; a PWM wave generation module configured to generate a PWM wave with a pulse width less than a turn-on process time of the transistor of the power transistor module, the PWM wave providing a drive signal for the transistor of the power transistor module; a driving module configured to receive and amplify the drive signal to drive the transistor of the power transistor module; and a switch module configured to control on-off of the redundancy discharge circuit.

Optionally, the PWM wave generated by the PWM wave generation module is a low duty cycle PWM wave.

Optionally, the transistor is an insulated gate bipolar transistor or a metal-oxide-semiconductor field-effect transistor.

Optionally, the power transistor module includes a transistor Q1 and a transistor Q2 connected in series, where the transistor Q1 is configured to turn the circuit on and off, the transistor Q2 is configured to dissipate the energy stored in the discharge element, and the PWM wave provides the drive signal for the transistor Q2.

Optionally, the driving module includes: a first driving sub-module and a second driving sub-module, where the first driving sub-module is configured to drive the transistor Q1, the second driving sub-module is configured to drive the transistor Q2, and the second driving sub-module receives the drive signal from the PWM wave generation module.

Optionally, the first driving sub-module and/or the second driving sub-module includes: a push-pull transistor formed by a transistor T1 and a transistor T2 and configured to drive the power transistor module.

Optionally, the switch module includes: a first switch sub-module and a second switch sub-module, where the first switch sub-module is connected in a drive branch where the transistor Q1 is located, and the second switch sub-module is connected in a drive branch where the transistor Q2 is located.

Optionally, a gate drive resistor is further connected in the push-pull transistor.

Optionally, two gate drive resistors are connected in each push-pull transistor, and the two gate drive resistors are respectively connected to the transistor T1 and the transistor T2 at either end connected to a power supply.

According to a second aspect, the present disclosure further provides a control method for a redundancy active discharge circuit, the method including: controlling, by a switch module, a redundancy discharge circuit to turn on; controlling a transistor Q1 to turn on; and generating, by a PWM wave generation module, a PWM wave with a pulse width less than a turn-on process time of a transistor of a power transistor module, to control the operation of a transistor Q2.

Optionally, the method further includes: generating a low duty cycle PWM wave by the PWM wave generation module.

Optionally, the method further includes: adjusting a magnitude of a resistance of a gate drive resistor to change a time at which the power transistor module is turned on and/or turned off.

According to a third aspect, the present disclosure provides an inverter used for a drive motor and equipped with the redundancy discharge circuit according to any one of the implementations in the first aspect, the inverter including legs connected to positive and negative electrodes of a power supply, where the power transistor module is implemented by legs of one or more phases of the inverter, the redundancy discharge circuit is configured to discharge the discharge element, and the legs are connected in parallel with the discharge element.

Optionally, the discharge element is a filter capacitor.

Optionally, the filter capacitor is a filter capacitor internal to the inverter or a filter capacitor external to the inverter and connected in parallel with the legs of the inverter.

Compared with the prior art, the present disclosure has the following advantages. The power transistor module is provided, which is connected to the discharge element and configured to dissipate the energy stored in the discharge element; the PWM wave generation module is provided, which is configured to generate the PWM wave with the pulse width less than the turn-on process time of the transistor of the power transistor module, the PWM wave providing the drive signal for the transistor in the power transistor module; the driving module is provided, which is configured to receive and amplify the drive signal to drive the transistor of the power transistor module; and the switch module is provided, which is configured to control on-off of the redundancy discharge circuit. Therefore, the present disclosure can implement a redundancy active discharge function only through simple logic control, and has the advantages of low cost, easy implementation, no need for software programming, and the like.

### BRIEF DESCRIPTION OF THE DRAWINGS

The accompanying drawings are included to provide a further understanding of the present application and are incorporated into and constitute a part of the present application, show embodiments of the present application, and serve to, together with the description, explain the principles of the present application.

FIG. 1 is a schematic diagram of a structure of a redundancy active discharge circuit according to an embodiment of the present disclosure;

FIG. 2 is an equivalent schematic diagram of discharge of a redundancy active discharge circuit according to an embodiment of the present disclosure;

FIG. 3 is a graph of the variation in voltages of a gate of a power transistor module in a turn-on process and a turn-off process according to an embodiment of the present disclosure;

FIG. 4 is a waveform graph of a PWM wave according to an embodiment of the present disclosure;

FIG. 5 is a graph of a switching waveform of a power transistor module under the control of a low duty cycle PWM wave according to an embodiment of the present disclosure;

FIG. 6 is a schematic flowchart of a control method for a redundancy active discharge circuit according to an embodiment of the present disclosure;

FIG. 7 is a graph of the variation in voltages of a gate of a power transistor module when being turned on and turned off after increasing a gate resistance according to an embodiment of the present disclosure; and

FIG. 8 is a graph of an actual gate drive waveform of a power transistor module under the drive of a low duty cycle PWM wave according to an embodiment of the present disclosure.

### DETAILED DESCRIPTION

To describe technical solutions of embodiments of the present application more clearly, the accompanying drawings required for describing the embodiments will be briefly described below. Obviously, the accompanying drawings described below show merely some of the examples or embodiments of the present application, and those of ordinary skill in the art would also have applied the present application to other similar scenarios according to these accompanying drawings without involving any creative effort. Unless obvious from the language context or otherwise illustrated, the same reference numerals in the drawings represent the same structure or operation.

As shown in the present application and the claims, unless the context expressly indicates otherwise, the words “a”, “an”, “said”, and/or “the” do not specifically refer to the singular, but may also include the plural. Generally, the terms “include” and “comprise” only suggest that the expressly identified steps and elements are included, but these steps and elements do not constitute an exclusive list, and the method or device may further include other steps or elements.

Unless otherwise indicated specifically, the relative arrangement, numerical expressions and values of the components and steps set forth in these embodiments do not limit the scope of the present application. In addition, it should be understood that, for ease of description, the dimensions of the various parts shown in the accompanying drawings are not drawn according to the actual proportional relationship. Techniques, methods and devices known to those of ordinary skill in the relevant field may not be discussed in detail, but where appropriate, the techniques, methods and devices should be considered as part of the authorized description. In all of the examples shown and discussed here, any specific value should be construed as merely exemplary but not limiting. Therefore, other examples of exemplary embodiments may have different values. It should be noted that similar reference signs and letters refer to similar items in the following drawings. Therefore, once an item is defined in one of the drawings, it is not necessary to further discuss the item in subsequent drawings.

In addition, it should be noted that, the use of terms such as “first” and “second” to define parts is merely for ease of facilitating differentiation of the corresponding parts. If not otherwise stated, the above terms have no special meanings and thus cannot be construed as limiting the scope of protection of the present application. Furthermore, although the terms used in the present application are selected from well-known common terms, some of the terms mentioned in the description of the present application may have been selected by the applicant according to his or her determination, and the detailed meaning thereof is described in the relevant section described herein. Furthermore, the present application must be understood, not simply by the actual terms used but also by the meanings encompassed by each term.

It should be understood that when a component is said to be “located on another component”, “connected to another component”, “coupled to another component”, or “in contact with another component”, it may be directly located on the other component, connected or coupled to the other component, or in contact with the other component, or there may be an intervening component. In contrast, when a component is said to be “directly located on another component”, “directly connected to another component”, “directly coupled to another component”, or “in direct contact with another component”, there is no intervening component. Similarly, when a first component is said to be “in electrical contact with” or “electrically coupled to” a second component, there is an electrical path between the first component and the second component that allows the flow of current. The electrical path can include a capacitor, coupled inductors, and/or other components that allow the flow of current, even without direct contact between conductive components.

A flowchart is used in the present application to illustrate the operations performed by the system according to the embodiments of the present application. It should be understood that the operations described above or below are not necessarily performed exactly in order. Instead, the various steps may be processed in reverse order or simultaneously. In addition, other operations are added to these processes, or a certain step or several operations are removed from these processes.

### Embodiment 1

In this embodiment, a structure of a redundancy active discharge (RAD) circuit mainly includes: a power transistor module including a transistor, where the power transistor module shown may include a single transistor, a plurality of transistors connected in parallel, or two or more transistors connected in series, or may be a power module formed by packaging a plurality of transistors together; and the power transistor module is connected to a discharge element and configured to dissipate energy stored in the discharge element; a pulse width modulation (PWM) wave generation module configured to generate a PWM wave with a pulse width less than a turn-on process time of the transistor of the power transistor module, the PWM wave providing a drive signal for the transistor of the power transistor module; a driving module configured to receive and amplify the drive signal to drive the transistor of the power transistor module; and a switch module configured to control on-off of the redundancy discharge circuit. Preferably, the PWM wave has a smaller duty cycle than that of a drive waveform of the transistor of the power transistor module.

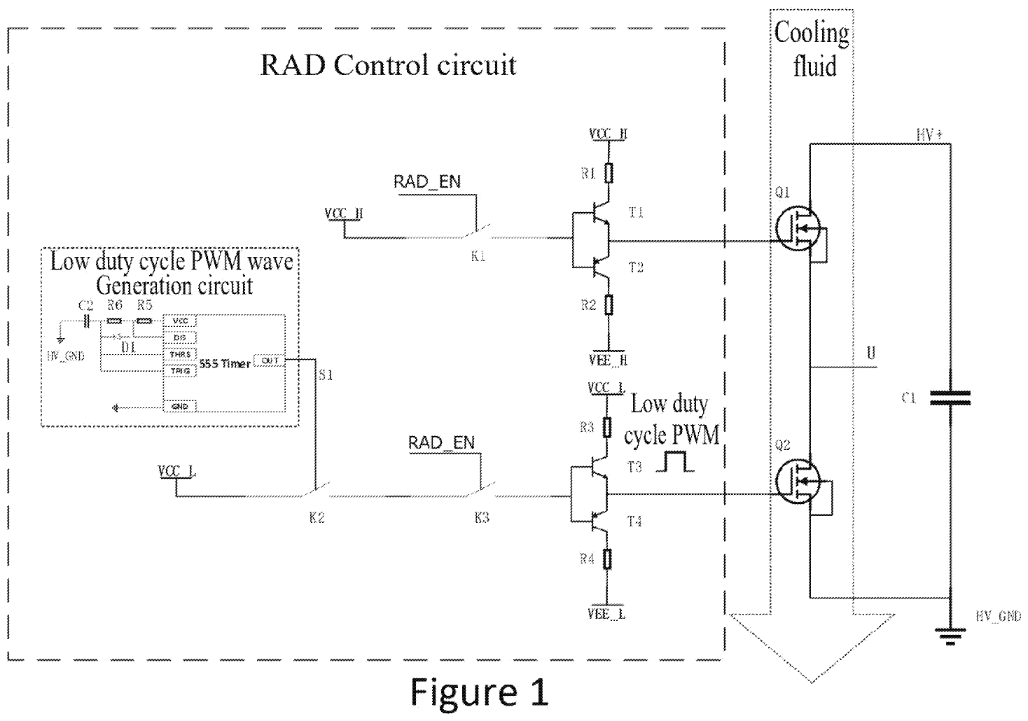

FIG. 1 is a schematic diagram of a structure of a redundancy active discharge circuit according to an embodiment of the present disclosure. Referring to FIG. 1, in an example, the power transistor module may include a transistor Q1 and a transistor Q2 connected in series. The transistor Q1 is mainly configured to turn the circuit on and off. Of course, the transistor Q1 also generates a small amount of heat. The transistor Q2 is configured to dissipate the energy stored in the discharge element. As can be understood by those skilled in the art, it is also possible that the transistor Q2 is mainly configured to turn the circuit on and off and the transistor Q1 is configured to dissipate the energy stored in the discharge element, or that only a transistor configured to dissipate the energy stored in the discharge element is included. Exemplarily, the power transistor module of this redundancy active discharge circuit may be implemented by three legs of a three-phase bridge circuit of an inverter, or may be controlled only by one or two legs selected from the legs. The power transistor module functions to release the energy stored in the discharge element, such as acting as a filter capacitor C1 shown in FIG. 1. The filter capacitor C1 may be a DC bus capacitor, or may be other capacitors connected in parallel with the legs of the inverter. When the filter capacitor C1 is discharged, the transistor Q1 of one leg is controlled to turn on, and the on-off of the transistor Q2 is controlled with a pulse width less than the turn-on process time of the transistor of the power transistor module, such that the transistor Q2 provides an effective resistance to enable a circuit discharge function.

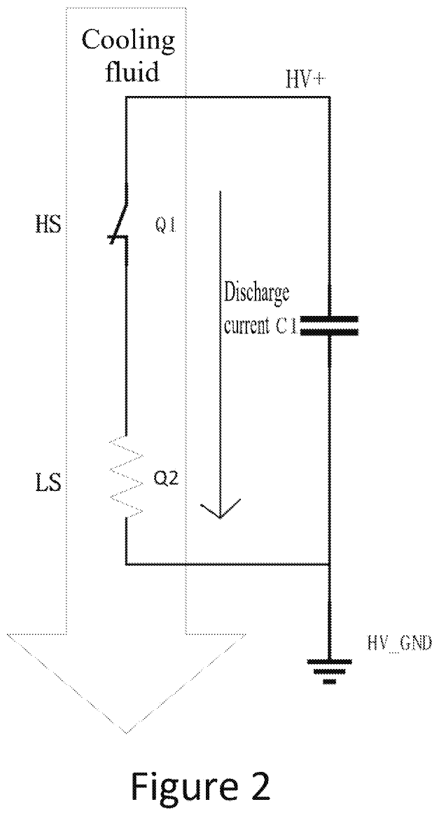

FIG. 2 is a schematic equivalent diagram of discharge of a redundancy active discharge circuit according to an embodiment of the present disclosure. As shown in FIG. 2, the redundancy active discharge circuit of this embodiment may be equivalent to: a simple circuit with the charged filter capacitor C1 as the discharge element, the transistor Q1 as an equivalent switch, and the transistor Q2 as an equivalent resistor. After this circuit is turned on, a discharge current can be formed, and then the transistor Q2 can generate heat, i.e., the transistor Q2 can dissipate the electric energy on the filter capacitor C1 that needs to be released, thereby achieving the purpose of discharge.

The redundancy active discharge circuit of this embodiment needs to generate a PWM wave with an appropriate duty cycle, to control the transistor Q2 at a low side, thereby preventing over-current and over-temperature of the transistor Q1 and the transistor Q2 in the circuit. When this circuit is operating, the transistor Q1 is fully turned on, and generates a small amount of heat because there are mainly conduction losses in this transistor, while the transistor Q2 is operating in a variable-resistance region and thus may generate a large amount of heat. The discharge circuit of this embodiment is applicable to existing half-bridge structures of the inverter, and allows the electric energy in the filter capacitor C1 to be dissipated through the power transistor module without providing additional electronic components with the circuit. As shown in FIG. 1, it can be seen that the heat generated by the power transistor module can be brought away in a timely manner by a cooling fluid or an associated cooling system, such that the power transistor module can release the energy in the filter capacitor C1 in a timely and efficient manner.

In another example, the driving module may include a first driving sub-module and a second driving sub-module, where the first driving sub-module is configured to drive the transistor Q1, the second driving sub-module is configured to drive the transistor Q2, and the second driving sub-module receives the drive signal from the PWM wave generation module.

In some implementations, the redundancy active discharge circuit may not have the transistor Q1, but may directly use the transistor Q2 as a component of the power transistor module to achieve the purpose of power consumption reduction and heat dissipation. In order to utilize the existing structure of the inverter in the prior art and reduce changes to the device structure, this discharge circuit is commonly applied in a scenario where the existing half-bridge structure of the inverter is utilized. Exemplarily, the transistor Q1 and the transistor Q2 of FIG. 1 are used as an example. The transistor Q1 and the transistor Q2 are transistors connected in series in a half bridge of an inverter, and may be insulated gate bipolar transistors (IGBTs) or metal-oxide-semiconductor field-effect transistors (MOSFETs). In this circuit configuration, in order to ensure that the filter capacitor C1, the transistor Q1, and the transistor Q2 can form a loop to generate a discharge current, the transistor Q1 is required to be in an on state during discharge.

In this embodiment, the on state of the transistor Q1 may be driven by the first driving sub-module such that the transistor Q1 can be turned on and off, and the on state of the transistor Q2 may be driven by the second driving sub-module such that the transistor Q2 can provide an effective resistance to implement discharge. It can be understood that the first driving sub-module and the second driving sub-module may have the same or different circuit configurations. In general, the first driving sub-module and the second driving sub-module employ the same circuit configuration, which can simplify the structural design of the redundancy active discharge circuit and the maintenance of the circuit in use.

In another example, the first driving sub-module and/or the second driving sub-module may include a push-pull transistor, which is formed by a transistor T1 and a transistor T2 and configured to drive the transistor of the power transistor module, or may be in the form of other circuits, such as other drive ICs. Referring to FIG. 1, the first driving sub-module includes a transistor T1 and a transistor T2. A collector of the transistor T1 is connected to a positive voltage, and an emitter thereof is connected to an emitter of the transistor T2, and a collector of the transistor T2 is connected to a negative voltage. The integral push-pull transistor formed by the transistor T1 and the transistor T2 has an input end connected to a supply voltage and an output end connected to a gate of the transistor Q1, thereby driving the transistor Q1. Similarly, the second driving sub-module includes a transistor T3 and a transistor T4. A collector of the transistor T3 is connected to a positive voltage, and an emitter thereof is connected to an emitter of the transistor T4, and a collector of the transistor T4 is connected to a negative voltage. The integral push-pull transistor formed by the transistor T3 and the transistor T4 has an input end connected to a supply voltage and an output end connected to a gate of the transistor Q2, thereby driving the transistor Q2. In this example, the second driving sub-module has the same configuration as the first driving sub-module. However, for clarity of description and for distinction from the first driving sub-module, the transistors of the second driving sub-module are denoted by the transistor T3 and the transistor T4, respectively. In FIG. 1, “VCC_H” and “VEE_H” are power supplies for high-side power switches, and “VCC_L” and “VEE_L” are power supplies for low-side power switches.

In another example, the switch module may include a first switch sub-module and a second switch sub-module, where the first switch sub-module is connected in a drive branch where the transistor Q1 is located, and the second switch sub-module is connected in a drive branch where the transistor Q2 is located. Exemplarily, as shown in FIG. 1, a switch K1 (the first switch sub-module) is connected in the drive branch of the transistor Q1, and a switch K3 (the second switch sub-module) is connected in the drive branch of the transistor Q2. The switch K1 is configured to control on-off of the branch of the redundancy discharge circuit where the transistor Q1 is located, and the switch K3 is configured to control on-off of the branch of the redundancy discharge circuit where the transistor Q2 is located. Further, the switch K1 and the switch K3 may be semiconductor switching devices. In FIG. 1, a “RAD_EN” switching signal may be triggered by software or other hardware signals.

In another example, a gate drive resistor is further connected in the push-pull transistor. Further, two gate drive resistors may be connected in each push-pull transistor, and the two gate drive resistors are respectively connected to the transistor T1 and the transistor T2 at either end connected to a power supply. As shown in FIG. 1, resistors R1, R2, R3, and R4 are the gate drive resistors. After the gate drive resistors are provided, a time at which the transistor of the power transistor module is turned on and/or turned off can be increased or decreased by adjusting the magnitude of resistances of the gate drive resistors.

In another example, the PWM wave generated by the PWM wave generation module is a low duty cycle PWM wave.

As shown in FIG. 1, S1 is a PWM wave generation circuit, i.e., a pulse width modulation circuit, which may generate a low duty cycle PWM wave with a pulse width less than a turn-on process time of the transistor of the power transistor module to drive a switch K2, where the switch K2 is connected in the drive branch where the transistor Q2 is located. The pulse width modulation circuit provides a control signal for a power element, and may also monitor an output state of a power circuit. Exemplarily, the low duty cycle PWM wave may be generated using a 555 chip in combination with externally configured elements including a diode D1, a capacitor C2, a resistor R5, and a resistor R6.

FIG. 3 is a graph of the variation in voltages of a gate of a power transistor module in a turn-on process and a turn-off process according to an embodiment of the present disclosure. Referring to FIG. 3, the turn-on and turn-off waveform of the gate is not a standard PWM waveform due to factors such as a gate resistance, a gate capacitance, and a parasitic inductance of the transistor. The transistor is equivalent to a variable resistor during turn-on and turn-off of the transistor.

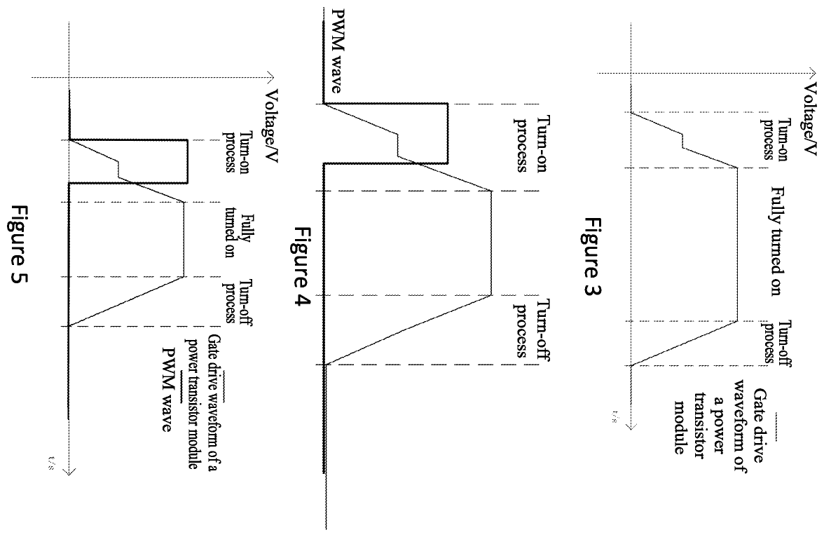

FIG. 4 is a waveform graph of a PWM wave according to an embodiment of the present disclosure, and FIG. 5 is a graph of a switching waveform of a power transistor module under the control of a low duty cycle PWM wave with a pulse width less than the turn-on process time of the transistor of the power transistor module according to an embodiment of the present disclosure. Referring to FIG. 4 and FIG. 5, in this embodiment, a PWM generation circuit mainly functions to convert an amplitude of an input voltage into a pulse with a certain width. This function can be used for controlling turn-on and turn-off of the transistor of the power transistor module, for example, for turning the transistor off by using the low duty cycle PWM wave when the transistor is not fully turned on. In this way, a current flowing through HS and LS switches is limited by the duty cycle of the PWM wave to prevent over-current and over-heating.

In this embodiment, a discharge time of the redundancy active discharge circuit can be flexibly adjusted according to an actual situation of a project. It can be used easily and conveniently in a circuit. Specifically, the magnitude of the resistances of the gate drive resistors R1, R2, R3, and R4 can be adjusted to increase or decrease the turn-on time and the turn-off time of the switch. In addition, the duty cycle of the PWM wave can be adjusted.

In the redundancy active discharge circuit provided in this embodiment, the power transistor module is provided, which is connected to the discharge element and configured to dissipate energy stored in the discharge element; the PWM wave generation module is provided, which is configured to generate the low duty cycle PWM wave with the pulse width less than the turn-on process time of the transistor of the power transistor module, the PWM wave providing the drive signal for the transistor of the power transistor module; the driving module is provided, which is configured to receive and amplify the drive signal to drive the transistor of the power transistor module; and the switch module is provided, which is configured to control on-off of the redundancy discharge circuit. Therefore, the redundancy active discharge circuit can implement a redundancy active discharge function only through simple logic control, and has the advantages of low cost, easy implementation, no need for software programming, and the like, especially when being applied in a phase half-bridge inverter circuit.

It should be noted that although in this embodiment, the PWM wave with the pulse width less than the turn-on process time of the transistor of the power transistor module is the low duty cycle PWM wave, the duty cycle of the PWM wave is not limited thereto.

### Embodiment 2

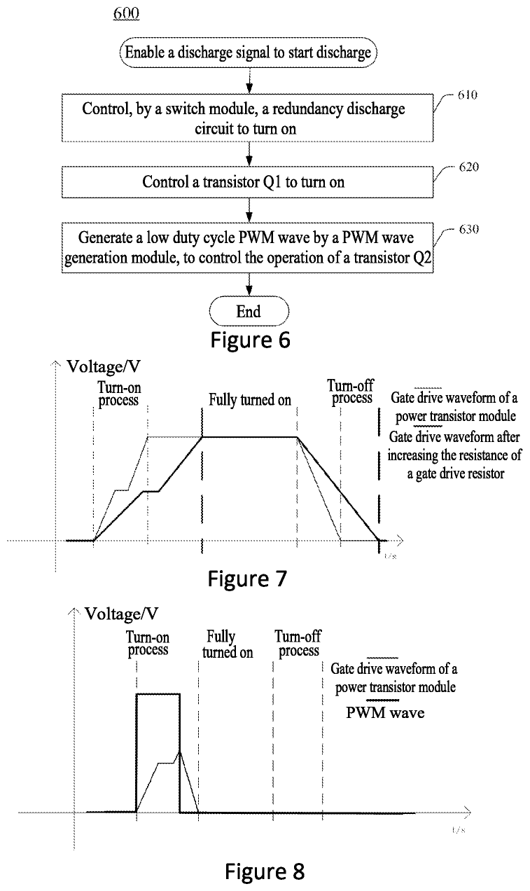

FIG. 6 is a schematic flowchart of a control method for a redundancy active discharge circuit according to an embodiment of the present disclosure. Referring to FIG. 6, the method 600 shown can be applied to the redundancy active discharge circuit of Embodiment 1. The method includes the following steps.

S610: Control, by the switch module, the redundancy discharge circuit to turn on.

In this embodiment, the switch module includes the first switch sub-module and the second switch sub-module. As shown in FIG. 1, the switch K1 is configured to control on-off of the branch of the redundancy discharge circuit where the transistor Q1 is located, and the switch K2 is configured to control on-off of the branch of the redundancy discharge circuit where the transistor Q2 is located. In FIG. 1, the “RAD_EN” switching signal may be triggered by software or other hardware signals, indicating that the switch K1 and the switch K3 are enabled to turn on.

S620: Control the transistor Q1 to turn on.

In this embodiment, the transistor Q1 and the transistor Q2 in FIG. 1 are used as an example. The transistor Q1 and the transistor Q2 are two transistors connected in series in a half bridge of an inverter, and may be either IGBTs or MOSFETs. In this circuit configuration, in order to ensure that the filter capacitor C1, the transistor Q1, and the transistor Q2 can form a loop to generate a discharge current, the transistor Q1 is required to be in an on state during discharge. The on-state of the transistor Q1 may be driven by the first driving sub-module such that the transistor Q1 can be turned on and off. The on-state of the transistor Q2 may be driven by the second driving sub-module such that the transistor Q2 can operate in an effective variable-resistance region to act as an equivalent resistor so as to implement discharge. Therefore, this redundancy active discharge circuit is operated on the premise that a high-side power switch (HS) transistor Q1 is fully turned on.

S630: Generate, by the PWM wave generation module, the PWM wave with the pulse width less than the turn-on process time of the transistor of the power transistor module, to control the operation of the transistor Q2.

In this embodiment, the switch K2 is controlled by the PWM wave generated by the PWM wave generation circuit S1. The low duty cycle PWM wave is subjected to power amplification by the push-pull transistors T3 and T4 to drive the low-side power switch (LS) transistor Q2, and then the energy stored in the direct current bus filter capacitor C1 may be dissipated in the transistor Q2 and the transistor Q1, certainly mainly in the transistor Q2.

In an example, the PWM wave generation module generates such a PWM wave with a low duty cycle, which can achieve the effect of turning the transistor of the power transistor module off before the transistor of the power transistor module is fully turned on.

In another example, the magnitude of the resistances of the gate drive resistors may also be adjusted to change the turn-on time and the turn-off time of the transistor of the power transistor module.

A detailed explanation of how to control on-off of the transistor of the power transistor module and other waveforms is given below.

FIG. 3 is a graph of the variation in voltages of a gate of a power transistor module in a turn-on process and a turn-off process according to an embodiment of the present disclosure. Referring to FIG. 3, usually, the transistor (Mosfet or IGBT) of the power transistor module is driven by the PWM wave generated by a main microcontroller unit (MCU) and then driven by a gate driver. However, due to factors such as a gate resistance, a gate capacitance, and a parasitic inductance of the transistor, the turn-on and turn-off waveform of the gate is not a standard PWM waveform. As can be seen from the gate switching waveform shown in FIG. 3, the gate voltage gradually increases during the turn-on process of the transistor, stabilizes after the transistor is fully turned on, and then gradually decreases during the turn-off process of the transistor. It can be seen that the gate voltage waveform for the turn-on and turn-off of the transistor is not a standard PWM waveform, and that the gate voltage varies gradually during both the turn-on process and the turn-off process.

FIG. 7 is a graph of the variation in voltages of a gate of a power transistor module when being turned on and turned off after increasing a gate resistance according to an embodiment of the present disclosure. Referring to FIG. 7, a drive current of the gate can be adjusted, for example, the magnitude of the gate resistance can be adjusted, to change the time for the turn-on process and the turn-off process of the transistor of the power transistor module. Exemplarily, if the resistance of the gate drive resistor is increased, the drive current is decreased, such that the time for the turn-on process and the turn-off process of the transistor of the power transistor module can be extended, in which case the switching waveform of the gate thereof will become the waveform as shown by the bold line in FIG. 7. It can be seen that although a final voltage of the transistor in the turn-on process and a final voltage of the transistor in the turn-off process are both the same as that when the gate drive resistors are not adjusted, the time for both the turn-on process and the turn-off process has been increased; and vice versa.

FIG. 5 is a graph of a switching waveform of a power transistor module under the control of a low duty cycle PWM wave with a pulse width less than the turn-on process time of the transistor of the power transistor module according to an embodiment of the present disclosure, and FIG. 8 is a graph of an actual gate drive waveform of a power transistor module under the drive of a low duty cycle PWM wave with a pulse width less than the turn-on process time of the transistor of the power transistor module according to an embodiment of the present disclosure. Referring to FIG. 5 and FIG. 8, this embodiment enables a redundancy active discharge function of a controller by taking advantage of the feature that the transistor is in a linear operating region during the turn-on process and has similar characteristics to a resistor. For example, the PWM wave generation module generates a low duty cycle PWM wave with a pulse width less than the turn-on process time of the transistor, such that the transistor of the power transistor module is turned off before the transistor of the module is fully turned on.

The pulse width of the low duty cycle PWM wave needs to be set depending on the actual driving capability and heat dissipation capability of the transistor. In an example, the upper transistor (the transistor Q1) of the half-bridge has been fully turned on, while the lower transistor (the transistor Q2) is turned on like a resistor, such that the transistor Q2 may generate a relatively large current and the power transistor module may heat up. If the current is so large that the power transistor module heats up seriously, the pulse width of the PWM wave can be reduced. On the contrary, if the current is not too large and the power transistor module does not heat up seriously, the pulse width of the PWM wave can be increased.

In this embodiment, a high-level voltage and a low-level voltage of the low duty cycle PWM wave can turn the transistor on and off normally. A high voltage level and a low voltage level should be within a range of parameters of a datasheet of the transistor, and the high-level voltage may be greater than a threshold voltage of a transistor gate.

According to the control method for a redundancy active discharge circuit provided in this embodiment, the redundancy discharge circuit is controlled by the switch module to turn on, then the transistor Q1 is controlled to turn on, and the PWM wave with the pulse width less than the turn-on process time of the transistor of the power transistor module is generated by the PWM wave generation module to control and drive the transistor of the power transistor module in combination with a PWM wave with an appropriate duty cycle. Therefore, the method implements a redundancy active discharge function, and has the advantages of low cost, easy implementation, no need for software programming, and the like, especially when being applied in a phase half-bridge inverter circuit.

### Embodiment 3

This embodiment provides an inverter for a drive motor, which inverter is equipped with the redundancy discharge circuit as shown in Embodiment 1. The inverter shown includes legs connected to positive and negative electrodes of a power supply, and a power transistor module is implemented by legs of one or more phases of the inverter. The redundancy discharge circuit is configured to discharge a discharge element, and the legs are connected in parallel with the discharge element.

In an example, the discharge element is a filter capacitor.

In another example, the filter capacitor is a filter capacitor internal to the inverter or a filter capacitor external to the inverter and connected in parallel with the legs of the inverter.

The inverter provided in this embodiment employs the redundancy discharge circuit as shown in Embodiment 1, to implement a redundancy active discharge function through simple logic control, and has the advantages of low cost, easy implementation, no need for software programming, and the like.

The basic concepts have been described above. Obviously, for those skilled in the art, the above disclosure of the present disclosure is merely used as an example and does not constitute a limitation on the present application. Although not explicitly stated herein, various modifications, improvements and amendments may be made to the present application by those skilled in the art. Such modifications, improvements and amendments are suggested in the present application, and therefore, such modifications, improvements and amendments still fall within the spirit and scope of the exemplary embodiments of the present application.

Meanwhile, the present application uses specific terms to describe the embodiments of the present application. For example, “one embodiment”, “an embodiment”, and/or “some embodiments” mean a feature, structure, or characteristic associated with at least one embodiment of the present application. Therefore, it should be emphasized and noted that two or more references to “an embodiment” or “one embodiment” or “an alternative embodiment” in various places in this specification do not necessarily indicate the same embodiment. Furthermore, some features, structures, or characteristics of the one or more embodiments of the present application may be combined appropriately.

Similarly, it should be noted that to simplify the expressions in the disclosure of the present application to assist in the understanding of one or more embodiments of the present disclosure, a plurality of features may sometimes be incorporated into an embodiment and accompanying drawing, or a description thereof in the foregoing description of the embodiments of the present application. However, such a method of disclosure does not mean that the subject of the present application requires more features than those mentioned in the claims. In fact, the features of the embodiments are less than all the features of a single embodiment disclosed above.

Figures for describing the quantity of components and attributes are used in some embodiments. It should be understood that such figures for use in the description of the embodiments are modified with modifiers “about,” “approximately,” or “substantially” in some examples. Unless otherwise specified, “about,” “approximately,” or “substantially” indicates that a variation of ±20% is allowed for the figures. Accordingly, in some embodiments, numerical parameters used in the description and the claims are all approximations, which can change depending on desired characteristics of individual embodiments. In some embodiments, for the numerical parameters, a specified number of valid digits should be considered, and a general bit retention method is used. Although numerical fields and parameters used to confirm the breadth of their ranges in some embodiments of the present application are approximations, such values are set to the extent practicable as precisely as possible in specific embodiments.

While the present application has been described with reference to the specific embodiments at hand, those of ordinary skill in the art would realize that the above embodiments are merely used to illustrate the present application, and various equivalent changes or substitutions can also be made without departing from the spirit of the present application. Therefore, any change and variation made to the above embodiments within the substantial spirit and scope of the present application shall fall within the scope of the claims of present application.

1. A redundancy active discharge circuit, comprising:
a power transistor module comprising at least one transistor, the power transistor module being connected to a discharge element and configured to dissipate energy stored in the discharge element;
a PWM wave generator configured to generate a pulse width modulated (PWM) wave with a pulse width less than a turn-on process time of the at least one transistor of the power transistor module, the PWM wave providing a drive signal for the at least one transistor of the power transistor module;
a driver configured to receive and amplify the drive signal to drive the at least one transistor of the power transistor module; and
a switch configured to control on-off of the redundancy active discharge circuit.

2. The redundancy active discharge circuit according to claim 1, wherein the PWM wave generated by the PWM wave generator is a low duty cycle PWM wave.

3. The redundancy active discharge circuit according to claim 1, wherein
the at least one transistor is an insulated gate bipolar transistor or a metal-oxide-semiconductor field-effect transistor.

4. The redundancy active discharge circuit according to claim 1, wherein
the at least one transistor of the power transistor module comprises a first transistor and a second transistor connected in series, wherein the first transistor is configured to turn the redundancy active discharge circuit on and off, the second transistor is configured to dissipate the energy stored in the discharge element, and the PWM wave provides the drive signal for the second transistor.

5. The redundancy active discharge circuit according to claim 4, wherein the driver comprises:
a first driving sub-module and a second driving sub-module,
wherein the first driving sub-module is configured to drive the first transistor,
the second driving sub-module is configured to drive the second transistor, and
the second driving sub-module receives the drive signal from the PWM wave generator.

6. The redundancy active discharge circuit according to claim 5, wherein the first driving sub-module and/or the second driving sub-module comprises:
a push-pull transistor formed by a third transistor and a fourth transistor, and configured to drive the power transistor module.

7. The redundancy active discharge circuit according to claim 6, wherein
a gate drive resistor is further connected in the push-pull transistor.

8. The redundancy active discharge circuit according to claim 7, wherein
two gate drive resistors are connected in each push-pull transistor, and the two gate drive resistors are respectively connected to the third transistor and the fourth transistor at either end connected to a power supply.

9. The redundancy active discharge circuit according to claim 4, wherein the switch comprises:
a first switch sub-module and a second switch sub-module,
wherein the first switch sub-module is connected in a drive branch where the first transistor is located, and
the second switch sub-module is connected in a drive branch where the second transistor is located.

10. A control method for a redundancy active discharge circuit, the method comprising:
controlling, by a switch, a redundancy active discharge circuit to turn on;
controlling a first transistor of a power transistor module to turn on, the power transistor module being connected to a discharge element and configured to dissipate energy stored in the discharge element; and
generating, by a PWM wave generator, a pulse width modulated (PWM) wave with a pulse width less than a turn-on process time of the first transistor of the power transistor module, to control operation of a second transistor of the power transistor module.

11. The control method according to claim 10, comprising:
generating a low duty cycle PWM wave by the PWM wave generator.

12. The control method according to claim 10, comprising:
adjusting a magnitude of a resistance of a gate drive resistor to change a time at which the power transistor module is turned on and/or turned off.

13. An inverter used for a drive motor, the inverter comprising:
the redundancy active discharge circuit according to claim 1; and
legs connected to positive and negative electrodes of a power supply,
wherein the power transistor module is implemented by legs of one or more phases of the inverter,
wherein the redundancy active discharge circuit is configured to discharge the discharge element, and
wherein the legs are connected in parallel with the discharge element.

14. The inverter according to claim 13, wherein the discharge element is a filter capacitor.

15. The inverter according to claim 14, wherein the filter capacitor is a filter capacitor internal to the inverter or a filter capacitor external to the inverter and connected in parallel with the legs of the inverter.
